(19) United States
(12) Patent Application Publication
(10) Pub. No.: US 2025/0221276 A1
(43) Pub. Date: Jul. 3, 2025

(54) DISPLAY APPARATUS

(71) Applicant: LG Display Co., Ltd., Seoul (KR)

(72) Inventors: KwangHyun BAEK, Paju-si (KR); Hyunjik BAE, Paju-si (KR)

(21) Appl. No.: 18/820,149

(22) Filed: Aug. 29, 2024

(30) Foreign Application Priority Data
Dec. 29, 2023 (KR) 10-2023-0196904

(51) Int. Cl. H10K 59/80; H10K 59/131; H10K 59/40; H10K 59/88

(52) U.S. Cl. CPC H10K 59/879; H10K 59/131; H10K 59/40; H10K 59/8792; H10K 59/88

(57) ABSTRACT

Disclosed is a display apparatus. The display apparatus includes a substrate including a first emitting area and a second emitting area. The display apparatus includes a first insulating layer disposed on the substrate and including a first opening corresponding to the first light emitting area and a second opening corresponding to the second light emitting area. The display apparatus includes a sensor electrode disposed on the first insulating layer, the sensor electrode corresponding to an area disposed between the first emitting area and the second emitting area. The first insulating layer includes a first side surface in contact with the first opening and an upper surface connected to the first side surface, and the sensor electrode is disposed on the first side surface and the upper surface of the first insulating layer.

### CROSS-REFERENCE TO RELATED APPLICATIONS

This application claims the benefit of the Korean Patent Application No. 10-2023-0196904 filed on Dec. 29, 2023, which is hereby incorporated by reference as if fully set forth herein.

### BACKGROUND

### Technical Field

The present disclosure relates to a display apparatus capable of controlling a viewing angle.

### Description of the Related Art

Electronic devices in various fields include display apparatus that display images. For example, a display apparatus for providing desired information or content to a driver and a passenger may be applied to a vehicle.

Among the display apparatus mounted on a vehicle, a display apparatus disposed at the center of the dashboard is in the process of being enlarged. This display apparatus needs to selectively provide information or content to a driver and/or a passenger according to a driving situation of a vehicle.

The contents of the background technology described above are technical information possessed by the inventor of the present disclosure to derive an example of the present disclosure or acquired in the process of deriving an example of the present disclosure, and may not necessarily be said to be a known technology disclosed to the general public prior to filing of the present disclosure.

### BRIEF SUMMARY

The present disclosure provides a display apparatus with improved luminous efficiency in the front.

In accordance with an aspect of the present disclosure, a display apparatus is provided. The display apparatus comprises a substrate including a first emitting area and a second emitting area, a first insulating layer disposed on the substrate and including a first opening corresponding to the first light emitting area and a second opening corresponding to the second light emitting area, and a sensor electrode disposed on the first insulating layer, the sensor electrode corresponding to an area disposed between the first emitting area and the second emitting area, wherein the first insulating layer includes a first side surface in contact with the first opening and an upper surface connected to the first side surface, and the sensor electrode is disposed on the first side surface and the upper surface of the first insulating layer.

And the above and other technical benefits can be accomplished by the provision of a display apparatus comprising a plurality of light emitting elements including a first light emitting element and a second light emitting element, a first light control element disposed in the first light emitting element, a second light control element disposed in the second light emitting element, and a sensor electrode disposed between the first light emitting element and the second light emitting element, wherein the sensor electrode is disposed between the first light control element and the second light control element, and the sensor electrode includes a first portion facing the first light control element and a second portion facing the second light control element.

### BRIEF DESCRIPTION OF THE SEVERAL VIEWS OF THE DRAWINGS

The above and other objects, features and other advantages of the present disclosure will be more clearly understood from the following detailed description taken in conjunction with the accompanying drawings, in which:

FIG. 1 is a diagram schematically illustrating a configuration of a display apparatus according to an embodiment.

FIG. 2 is a cross-sectional view schematically illustrating a structure of a display panel according to an embodiment.

FIG. 3 is a diagram schematically illustrating a configuration of a subpixel according to an embodiment.

FIGS. 4A and 4B are diagrams illustrating structures of the first and second light control elements according to an embodiment.

FIG. 5 is a diagram illustrating a display apparatus for a vehicle, to which the display apparatus is applied, according to an embodiment.

FIG. 6 is an equivalent circuit diagram illustrating a configuration of a subpixel according to an embodiment.

FIG. 7 is a diagram illustrating a driving waveform of a subpixel according to an embodiment.

FIG. 8 is an enlarged plan view illustrating an area A structure in the display panel according to an embodiment illustrated in FIG. 1.

FIG. 9 is a plan view illustrating a region A structure shown in FIG. 8 including a black matrix.

FIG. 10 is an enlarged plan view illustrating a structure of a pixel area among areas A shown in FIG. 8.

FIG. 11 is a plan view illustrating a structure of a pixel region illustrated in FIG. 10 including a black matrix.

FIG. 12 is a cross-sectional view illustrating a structure of a subpixel area along the line I-I′ in a pixel area illustrated in FIG. 11.

FIG. 13 is a cross-sectional view schematically illustrating a first light emitting region illustrated in FIG. 12, according to an embodiment.

FIG. 14 is a cross-sectional view schematically illustrating a first light emitting region illustrated in FIG. 12, according to another embodiment.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, dimensions (e.g., length, width, height, thickness, radius, diameter, area, etc.), ratios, angles, and numbers disclosed in the drawings for describing embodiments of the present disclosure are merely examples, and thus the present disclosure is not limited to the illustrated details.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically. The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

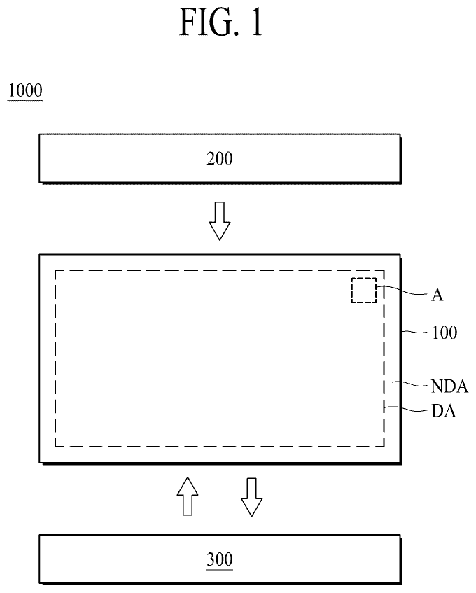

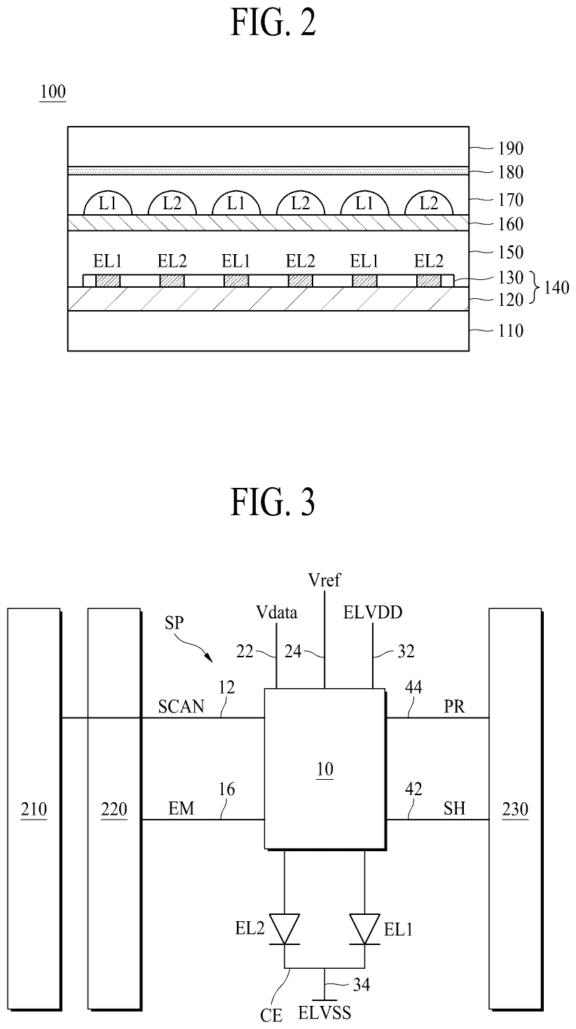

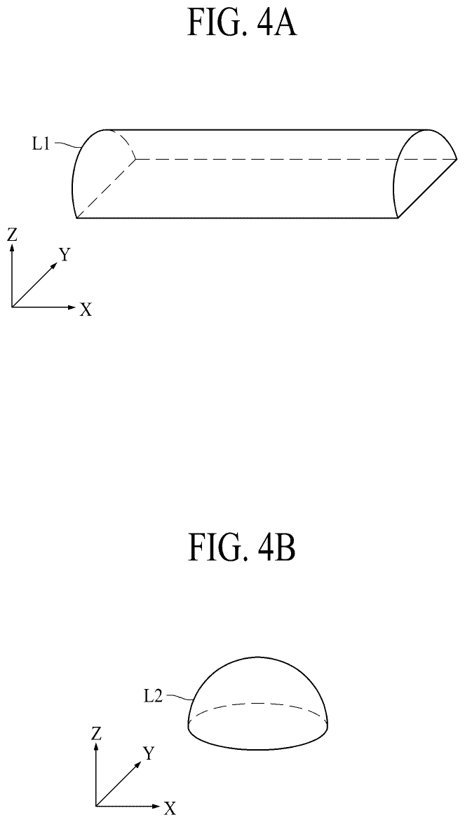

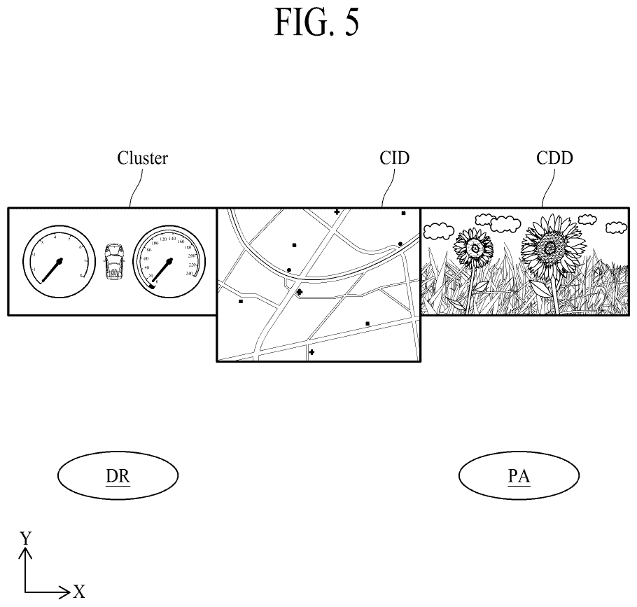

FIG. 1 is a diagram schematically illustrating a configuration of a display apparatus according to an embodiment, FIG. 2 is a cross-sectional view schematically illustrating a structure of a display panel according to an embodiment, FIG. 3 is a diagram schematically illustrating a configuration of a subpixel according to an embodiment, FIGS. 4A and 4B are diagrams illustrating structures of the first and second light control elements according to an embodiment, and FIG. 5 is a diagram illustrating a display apparatus for a vehicle to which the display apparatus according to an embodiment is applied.

The display apparatus 1000 according to an embodiment may provide both a display function for displaying an image and a touch sensing function for sensing the presence or absence of a user's touch and/or touch coordinates.

The display apparatus 1000 according to an embodiment may be an electroluminescent display apparatus including a touch sensor or a micro light emitting diode display apparatus. An electroluminescent display including a touch sensor may be an organic light emitting diode (OLED) display apparatus, a quantum-dot light emitting diode display apparatus, or an inorganic light emitting diode display apparatus.

Referring to FIG. 1, the display apparatus 1000 may include a display panel 100, a display driving circuit 200 for driving the display panel 100, and a touch sensing circuit 300 for driving and sensing a touch sensor array embedded into the display panel 100. The display apparatus 1000 may further include a power management circuit for generating and supplying a plurality of power voltages required for operations of the display panel 100, the display driving circuit 200, and the touch sensing circuit 300.

The display panel 100 may be a rigid display panel, or a flexible display panel capable of shape deformation such as a foldable, bendable, rollable, and stretchable display panel.

The display panel 100 may include a display area DA displaying an image and a non-display area NDA that is a bezel area surrounding the display area DA and positioned at the outer portion. The display panel 100 may further include a touch sensor array disposed in the display area DA to sense a user's touch.

The display panel 100 may display an image using the display area DA in which a plurality of subpixels are arranged in a matrix form. The pixel matrix of the display area DA may include a plurality of row lines consisting of a plurality of subpixels arranged in a first direction X and a plurality of column lines consisting of a plurality of subpixels arranged in a second direction Y. The display panel 100 may include a plurality of signal lines including a plurality of gate lines, a plurality of data lines, a plurality of power lines, and the like connected to a plurality of subpixels.

The plurality of subpixels may include a red subpixel emitting red light, a green subpixel emitting green light, and a blue subpixel emitting blue light. The plurality of subpixels may further include a white subpixel emitting white light. The unit pixel may include at least two subpixels.

The display driving circuit 200 may include a data driver that supplies a data signal to a plurality of data lines of the display panel 100, a gate driver that supplies a gate signal to a plurality of gate lines, and a timing controller that controls the operation of the data driver and the gate driver.

The touch sensing circuit 300 may include a touch driving circuit that supplies a touch driving signal to a touch sensor array embedded into the display panel 100, and receives a readout signal from the touch sensor array to generate sensing data, and a touch controller that detects the presence or absence of a touch and a touch coordinate position based on sensing data supplied from the touch driving circuit, and the like.

The touch sensor array may use a self-capacitance method that senses a change in self-capacitance according to a touch, or a mutual-capacitance method that senses a change in mutual-capacitance according to a touch.

The display panel 100 according to an embodiment may control a viewing angle according to a viewing angle mode. The display area DA of the display panel 100 may display an image in a first viewing angle mode in which a viewing angle with respect to the first direction is relatively wide or a second viewing angle mode in which a viewing angle with respect to the first direction is narrower than that of the first viewing angle mode. The first viewing angle mode may be expressed as a wide viewing angle mode or a shared mode. The second viewing angle mode may be expressed as a narrow viewing angle mode or a privacy mode. The display area DA of the display panel 100 may be driven in a switchable privacy mode (SPM) capable of switching the sharing mode and the privacy mode.

Referring to FIG. 2, the display panel 100 according to an embodiment may include a pixel array 140 including a circuit element layer 120 including a plurality of transistors and a plurality of signal lines disposed on the substrate 110, and a light emitting element layer 130 including a plurality of light emitting elements EL1 and EL2 disposed on the circuit element layer 120, and an encapsulation layer 150 disposed on the pixel array 140 to seal the light emitting element layer 130. The display panel 100 may include a touch sensor array 160 including a plurality of sensor electrodes disposed on the encapsulation layer 150, and a light control array 170 including a plurality of light control elements L1 and L2 disposed on the touch sensor array 160. The display panel 100 may further include a cover substrate 190 coupled to the light control array 170 by an optical clear adhesive (OCA) 180.

Referring to FIGS. 2 and 3, the subpixel SP according to an embodiment capable of controlling a viewing angle includes a first light emitting element EL1, a second light emitting element EL2, and a pixel circuit 10 for dividing and driving the first and second light emitting elements EL1 and EL2 according to a viewing angle mode, and a first light control element (L1 of FIG. 2) may be overlapped on the first light emitting element EL1, and a second light control element (L2 of FIG. 2) may be overlapped on the second light emitting element EL2.

The subpixel SP according to an embodiment may drive the first light emitting element EL1 in the first viewing angle mode and emit light having the first viewing angle through the first light control element L1. The subpixel SP may drive the second light emitting element EL2 in the second viewing angle mode and emit light having a second viewing angle narrower than the first viewing angle through the second light control element L2.

Referring to FIG. 4A, the first light control element L1 may have a half-cylindrical lens structure long in the first direction X, and the lens structure is not limited thereto. Referring to FIG. 4B, the second light control element L2 may have a half-spherical lens structure, and the lens structure is not limited thereto. In an embodiment, the first light control element L1 and the second light control element L2 may control (or limit) differently a viewing angle in the first direction X and control (or limit) equally a viewing angle in the second direction Y.

Depending on the embodiment, the light control elements L1 and L2 may be formed of a fluid material, a semi-fluid material, or a solid. The material and configuration of the light control elements L1 and L2 are not limited to the above-described examples. In addition, in some cases, the light control elements L1 and L2 may be referred to as a light control layer, a light control configuration, a lens, or a viewing angle control unit, but are not limited to these terms.

In FIGS. 4A and 4B, the first direction X may represent the left and right directions (e.g., horizontal directions) of the display panel 100, the second direction Y may represent the up and down direction (e.g., vertical direction) of the display panel 100, and the third direction Z may represent the front and rear directions (e.g., thickness direction) of the display panel 100.

In the first viewing angle mode, each subpixel SP of the display panel 100 drives the first light emitting element EL1 and does not limit the path of light emitted from the first light emitting element EL1 to within a specific angle in the first direction X, thereby providing light having a wide viewing angle.

In the second viewing angle mode, each subpixel SP of the display panel 100 may drive the second light emitting element EL2 and limit a path of light emitted from the second light emitting element EL2 through the second light control element L2 to within a specific cut-off angle in the first direction X to provide light having a narrow viewing angle.

The first light control element L1 and the second light control element L2 may control the path of light in the second direction Y to be within the cut-off angle to be controlled at a narrow viewing angle. Accordingly, when the display apparatus 1000 is applied to a vehicle as shown in FIG. 5, an image displayed on the display apparatus 1000 may be prevented from being reflected by the front glass of the vehicle to interfere with the driver's view.

The subpixel SP according to an embodiment may receive the data voltage Vdata from the data driver of the display driving circuit 200 through any one data line 22. The subpixel SP may receive the scan signal SCAN from the gate driver of the display driving circuit 200 through at least one gate line 12, and may receive the emission control signal EM through at least one gate line 16. The subpixel SP may receive the first mode signal SH from the gate driver of the display driving circuit 200 through any one gate line 42, and may receive the second mode signal PR through any one gate line 44. The subpixel SP according to an embodiment may receive the high-potential power voltage ELVDD from the power management circuit through the first power line 32, the low-potential power voltage ELVSS through the common electrode (cathode electrode) CE and the second power line 34, and may receive the reference voltage Vref through the reference line 24.

The gate driver may be embedded and disposed in the non-display area NDA of the display panel 100, and it is not limited there to, the gate driver may be distributed and disposed in the display area DA. The gate driver according to an embodiment may be embedded in the display panel 100 in a gate in panel (GIP) type consisting of transistors formed in the same process as transistors of the display area DA.

The gate driver may include at least one scan driver 210 driving at least one gate line 12 and at least one emission control driver 220 driving at least one gate line 16. The number of gate lines connected to the subpixel SP, the number of scan drivers 210, and the number of emission control drivers 220 may be variously changed according to a detailed configuration of a pixel circuit constituting the subpixel SP.

The scan driver 210 may generate and supply at least one scan signal SCAN to at least one gate line 12 disposed in each of the plurality of pixel row lines.

The emission control driver 220 may generate and supply at least one emission control signal EM to at least one gate line 16 disposed in each of the plurality of pixel row lines.

In an embodiment, the gate driver may further include a mode control unit 230 for supplying mode signals SH and PR to the gate lines 42 and 44.

The mode control unit 230 may generate and supply a first mode signal SH through any one gate line 42 to each of a plurality of pixel row lines using a mode selection signal, and may generate and supply a second mode signal PR through any one of the gate lines 44. The mode control unit 230 may selectively drive the first light emitting element EL1 and the second light emitting element EL2 of each subpixel SP by using the first mode signal SH and the second mode signal PR.

In an embodiment, the first and second mode signals SH and PR may be supplied from the light emission control driver 220.

At least one of an LTPS transistor using a low temperature polysilicon (LTPS) semiconductor and an oxide transistor using a metal-oxide semiconductor may be applied to a plurality of transistors disposed in the display area DA of the display panel 100 and the non-display area NDA including the gate driver. The display panel 100 according to an embodiment may be configured such that an LTPS transistor and an oxide transistor coexist to reduce power consumption.

Referring to FIG. 5, a plurality of display apparatus disposed on a vehicle dashboard may include a cluster, a center information display CID, and a co-driver display CDD. A display apparatus that limits the viewing angle to within the cut-off angle in only the second direction Y for safe driving may be applied to the cluster and the central information display CID mainly used by the driver DR. A display apparatus including a touch sensor may be applied to the central information display CID. The display apparatus 1000 capable of controlling the viewing angle in the first viewing angle mode and the second viewing angle mode as in the above-described embodiment may be applied to the co-driver display CDD used by the driver DR and the passenger PA.

The co-driver display CDD 1000 may be driven in a first viewing angle mode under the control of the host system when the driver DR is not driving, and may provide an image having a wide viewing angle in the first direction X to the driver DR and the passenger PA.

When the driver DR drives, the co-driver display CDD may be driven in the second viewing angle mode under the control of the host system, may limit the viewing angle to within the cut-off angle in the first direction X to provide an image having a narrow viewing angle to only the passenger PA, and may not provide an image to the driver DR so as not to interfere with driving.

The display apparatus 1000 according to an embodiment may be applied not only to a co-driver display CDD, but also to various display apparatus such as a mobile display, an IT display, and a TV display that selectively requires viewing angle control for privacy and information protection.

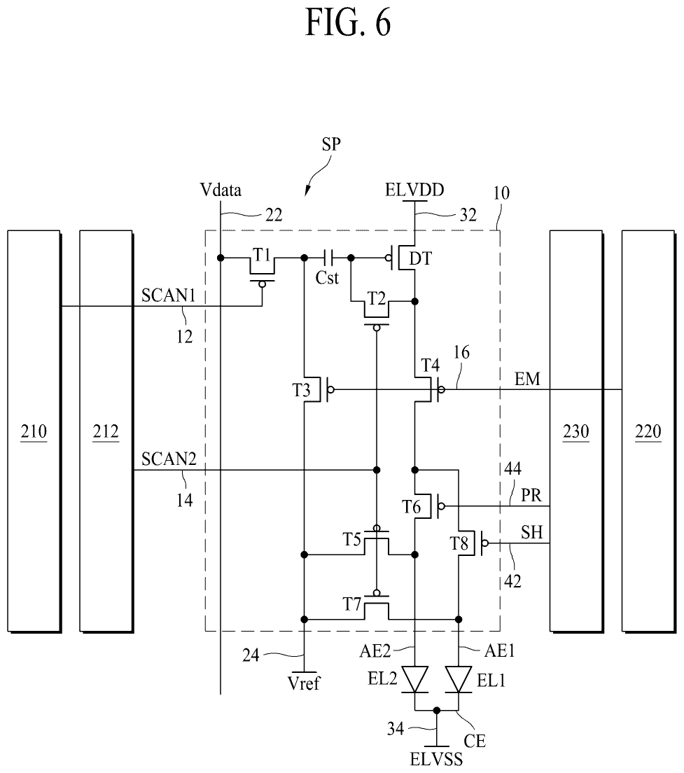

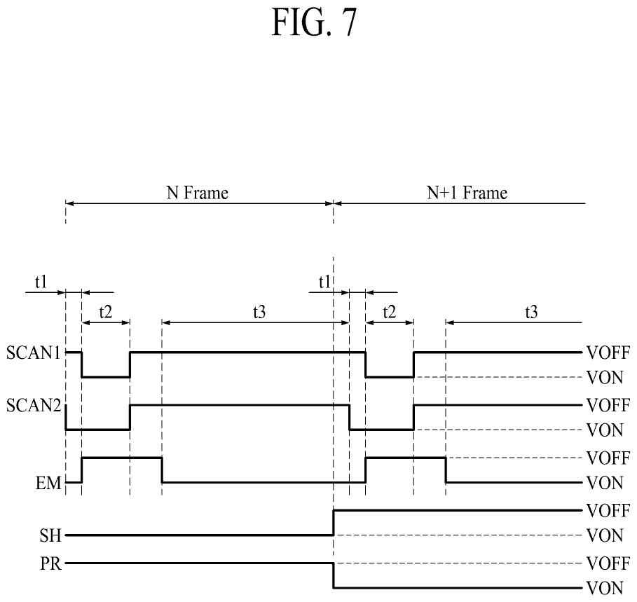

FIG. 6 is an equivalent circuit diagram illustrating a configuration of a subpixel according to an embodiment, and FIG. 7 is a diagram illustrating a driving waveform of a subpixel according to an embodiment.

Referring to FIG. 6, the subpixel SP may include first and second light emitting elements EL1 and EL2, and a pixel circuit 10 for separately driving the first and second light emitting elements EL1 and EL2. In an embodiment, the pixel circuit 10 may include a driving transistor DT, a plurality of switching transistors T1 to T8, and a storage capacitor Cst, but is not limited thereto.

The pixel circuit 10 may receive the first scan signal SCAN1 from the first scan driver 210 through the first gate line 12, and may receive the second scan signal SCAN2 from the second scan driver 212 through the second gate line 14. According to an embodiment, the first gate line 12 of FIG. 3 may include the first gate line 12 of FIG. 6.

The pixel circuit 10 may receive the emission control signal EM from the first emission control driver 220 through the third gate line 16.

In an embodiment, the pixel circuit 10 may receive the first mode signal SH from the mode control unit 230 through the fourth gate line 42, and may receive the second mode signal PR through the fifth gate line 44.

In an embodiment, the pixel circuit 10 may receive the first mode signal SH from the second light emission control driver 220 through the fourth gate line 42, and may receive the second mode signal PR through the fifth gate line 44.

The pixel circuit 10 may receive the data signal Vdata from the data driver through the data line 22. The pixel circuit 10 may receive the high potential power voltage ELVDD from the power management circuit through the first power line 32, the low potential power voltage ELVSS through the second power line 34 and the common electrode CE, and the reference voltage Vref through the reference line 24.

Referring to FIG. 7, the subpixel SP may be driven to include an initialization period t1, a sampling and writing period t2, and an emission period t3 for each frame period N and N+1. For convenience of description, in FIG. 7, the N frame period represents any one frame period of the first viewing angle mode, and the N+1 frame period represents any one frame period of the second viewing angle mode.

Each of the driving transistor DT and the plurality of switching transistors T1 to T8 of the pixel circuit 10 includes a gate electrode, a source electrode, and a drain electrode. Since the source electrode and the drain electrode are not fixed and may be changed according to the voltage and current direction applied to the gate electrode, one of the source electrode and the drain electrode may be expressed as the first electrode, and another one of the source electrode and the drain electrode may be expressed as the second electrode. The driving transistor DT and the plurality of switching transistors T1 to T8 of the pixel circuit 10 may use at least one of a polysilicon semiconductor, an amorphous silicon semiconductor, and an oxide semiconductor, and may use the P type or the N type and may be used in combination of the P type and the N type.

The first and second light emitting elements EL1 and EL2 may include the first electrodes AE1 and AE2 individually connected to the eighth and sixth switching transistors T8 and T6, the cathode electrode CE receiving the low potential power voltage ELVSS from the second power line 34, and the light emitting layer disposed between the first electrodes AE1 and AE2, and the cathode electrode CE. In the first and second light emitting elements EL1 and EL2, when driving current is supplied from the driving transistor DT through each of the eighth and sixth switching transistors T8 and T6, electrons from the cathode electrode CE are injected into the light emitting layer, and holes from the first electrodes AE1 and AE2 are injected into the light emitting layer to emit light having a brightness proportional to the current value of the driving current by emitting fluorescent materials or phosphorescent materials by recombination of electrons and holes in the light emitting layer.

The gate electrode of the driving transistor DT may be connected to the storage capacitor Cst, the first electrode may be connected to the first power line 32 supplying the high potential power voltage ELVDD, and the second electrode may be connected to the first electrode of the fourth switching transistor T4. The driving transistor DT may be connected in common to the first electrodes of the sixth and eighth switching transistors T6 and T8 through the fourth switching transistor T4. The driving transistor DT may drive the first light emitting element EL1 through the fourth and eighth switching transistors T4 and T8, or may drive the second light emitting element EL2 through the fourth and sixth switching transistors T4 and T6. The driving transistor DT may control the light emission intensity of the first light emitting element EL1 through the fourth and eighth switching transistors T4 and T8 or may control the light emission intensity of the second light emitting element EL2 through the fourth and sixth switching transistors T4 and T6 by controlling the driving current according to the driving voltage charged in the storage capacitor Cst.

The storage capacitor Cst may be connected between the second electrode of the first switching transistor T1 and the gate electrode of the driving transistor DT to charge a driving voltage corresponding to the data voltage Vdata. The storage capacitor Cst may hold the charged driving voltage during the light emission period t3 during which the first switching transistor T1 is turned off, and supply the driving voltage to the driving transistor DT.

The first switching transistor T1 may be turned on or turned off in response to the first scan signal SCAN1 of the first gate line 12 disposed in the ith (i is a natural number) pixel row line. The first switching transistor T1 may supply the data voltage Vdata supplied through the data line 22 to the first electrode of the storage capacitor Cst during the sampling and writing period t2 in which the first scan signal SCAN1 has the gate-on voltage VON. The switching transistor T1 may be turned off during the initialization period t1 and the light emission period t3 in which the first scan signal SCAN1 has the gate-off voltage VOFF.

The second, fifth, and seventh switching transistors T2, T5, and T7 may be turned on or off in response to the second scan signal SCAN2 supplied to the second gate line 14 of the i-th pixel row line. The second, fifth, and seventh switching transistors T2, T5, and T7 may be turned on during the initialization period t1 and the sampling and writing period t2 in which the second scan signal SCAN2 has the gate-on voltage VON, and may be turned off during the light emission period t3 in which the second scan signal SCAN2 has the gate-off voltage VOFF.

The second switching transistor T2 may connect the driving transistor DT in a diode structure by connecting the gate electrode of the driving transistor DT to the second electrode during the initialization period t1 and the sampling and writing period t2 in response to the second scan signal SCAN2. The second switching transistor T2 may charge the storage capacitor Cst by compensating the threshold voltage Vth of the driving transistor DT. Accordingly, the storage capacitor Cst may charge the data voltage compensated for the threshold voltage Vth of the driving transistor DT.

The fifth switching transistor T5 may supply the reference voltage Vref supplied through the reference line 24 to the first electrode AE2 of the second light emitting element EL2 during the initialization period t1 and the sampling and writing period t2 in response to the second scan signal SCAN2.

The seventh switching transistor T7 may supply the initialization voltage Vref supplied through the reference line 24 to the first electrode AE1 of the first light emitting element EL1 during the initialization period t1 and the sampling and writing period t2 in response to the second scan signal SCAN2.

The third and fourth switching transistors T3 and T4 may be turned on or turned off in response to the light emission control signal EM supplied to the third gate line 16 of the i-th pixel row line. The third and fourth switching transistors T3 and T4 may be turned on during the initialization period t1 and the light emission period t3 in which the light emission control signal EM has the gate-on voltage VON. The third and fourth switching transistors T3 and T4 may be turned off during the sampling and writing period t2 and a period between the sampling and writing period t2 and the light emission period t3 in which the light emission control signal EM has the gate-off voltage VOFF.

The third switching transistor T3 may supply the reference voltage Vref supplied through the reference line 24 to the first electrode of the storage capacitor Cst during the initialization period t1 and the light emission period t3 in response to the light emission control signal EM.

The fourth switching transistor T4 may connect the driving transistor DT to the sixth and eighth switching transistors T6 and T8 during the initialization period t1 and the light emission period t3 in response to the light emission control signal EM.

The eighth switching transistor T8 may be turned on or off in response to the first mode signal SH supplied to the fourth gate line 42 of the i-th pixel row line. The eighth switching transistor T8 may be turned on during the driving period N frame of the first viewing angle mode in which the first mode signal SH has the gate-on voltage VON, and may be turned off during the driving period N+1 frame of the second viewing angle mode in which the first mode signal SH has the gate-off voltage VOFF.

The eighth switching transistor T8 may connect the fourth switching transistor T4 to the first light emitting element EL1 during the driving period N frame of the first viewing angle mode in response to the first mode signal SH.

During the light emission period t3 of the driving period N frame of the first viewing angle mode, the driving transistor DT may drive the first light emitting element EL1 through the fourth and eighth switching transistors T4 and T8. Accordingly, the subpixel SP may provide light of the first viewing angle through the first light emitting element EL1 and the first light control element (see L1 of FIG. 4A).

The sixth switching transistor T6 may be turned on or off in response to the second mode signal PR supplied to the fifth gate line 44 disposed in the i-th pixel row line. The sixth switching transistor T6 may be turned on during the driving period N+1 frame of the second viewing angle mode in which the second mode signal PR has the gate-on voltage VON, and may be turned off during the driving period N frame of the first viewing angle mode in which the second mode signal PR has the gate-off voltage VOFF.

The sixth switching transistor T6 may connect the fourth switching transistor T4 to the second light emitting element EL2 during the driving period N+1 frame of the second viewing angle mode in response to the second mode signal PR.

During the light emission period t3 of the driving period N+1 frame of the second viewing angle mode, the driving transistor DT may drive the second light emitting element EL2 through the fourth and sixth switching transistors T4 and T6. Accordingly, the subpixel SP may provide light of the second viewing angle through the second light emitting element EL2 and the second light control element L2 (FIG. 4B).

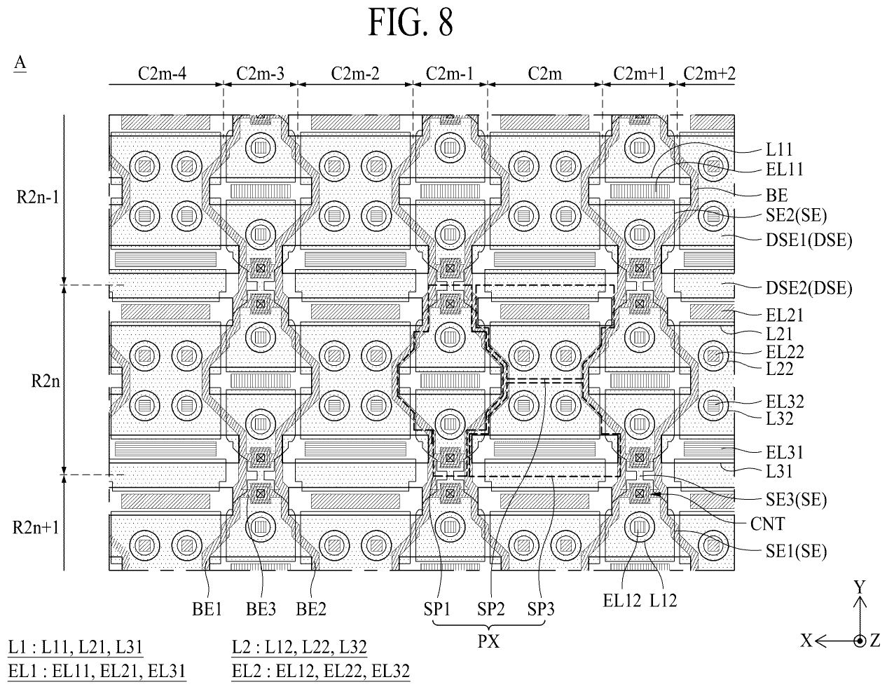

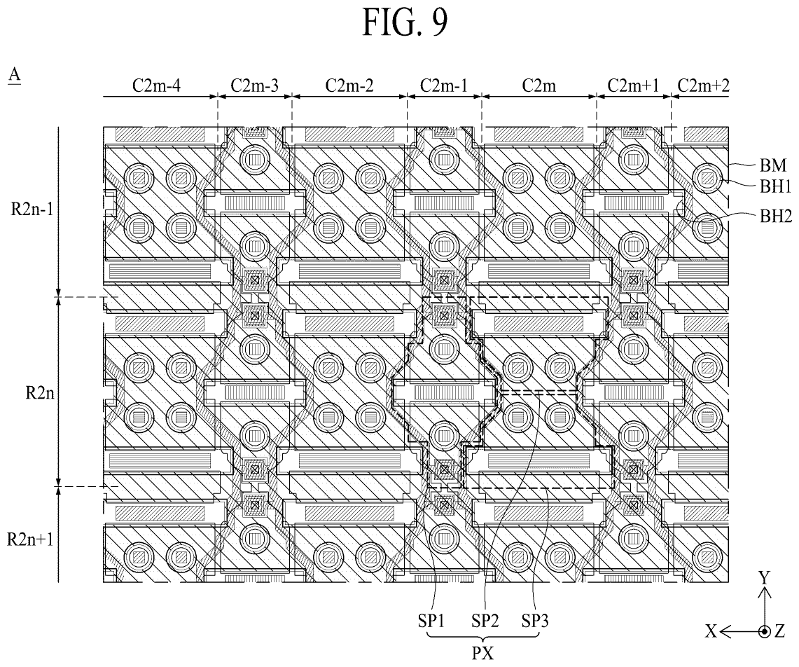

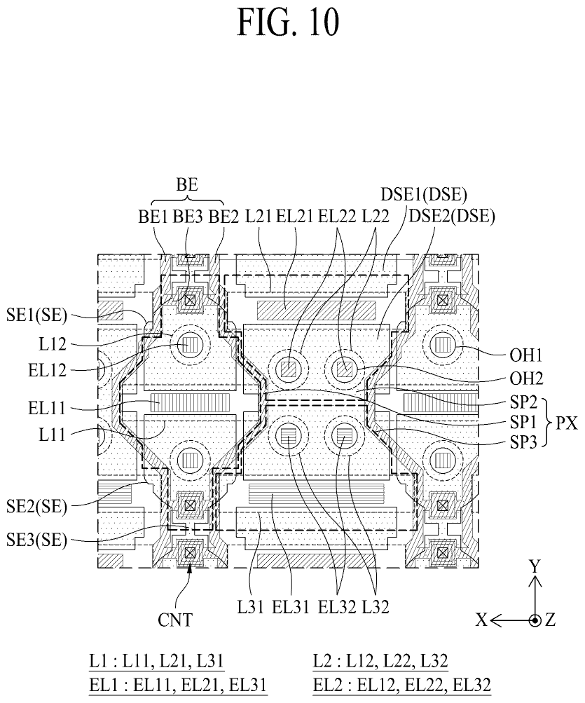

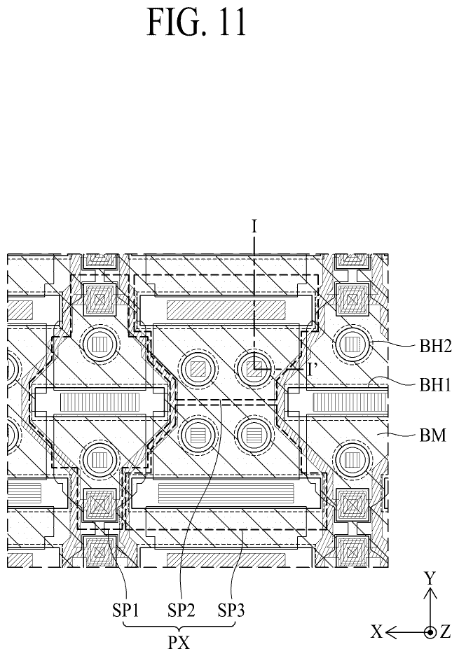

FIG. 8 is an enlarged plan view illustrating an area A structure in the display panel according to an embodiment illustrated in FIG. 1, FIG. 9 is a plan view illustrating an area A structure shown in FIG. 8 including a black matrix, FIG. 10 is an enlarged plan view illustrating a structure of a pixel area among areas A shown in FIG. 8, and FIG. 11 is a plan view illustrating a structure of a pixel area illustrated in FIG. 10 including a black matrix.

Referring to FIGS. 8 to 11, area A is an enlarged view of a plurality of pixel areas on the display panel 100 according to an embodiment illustrated in FIG. 1. The area A of the display panel 100 according to an embodiment may have a structure in which a pixel array, a touch sensor array, and a light control array at least partially overlap. The pixel array may include a plurality of subpixels SP1, SP2, and SP3 having a plurality of light emitting elements EL1: EL11, EL21, EL31, and EL2: EL12, EL22, EL32. The touch sensor array may include a plurality of sensor electrodes SE, a bridge electrode BE, a dummy electrode DSE, and a black matrix BM. The light control array may include a plurality of light control elements L1: L11, L21, L31, and L2: L12, L22, L32.

The pixel array may include a 2n-1 row line R2n−1, (n is a natural number) and a 2n row line R2n including a plurality of subpixels SP1, SP2, and SP3 arranged in the first direction X, and a 2m−1 column line C2m−1, (m is a natural number) and a 2m column line C2m including a plurality of subpixels SP1, SP2, and SP3 arranged in the second direction Y.

The 2m−1 column line C2m−1 may include a plurality of first type subpixels SP1 arranged in the second direction Y. The 2m column line C2m may include a plurality of second and third type subpixels SP2 and SP3 alternately arranged in the second direction Y.

Each of the 2n−1 row line R2n−1 and the 2n row line R2n may include a plurality of first to third type subpixels SP1, SP2, and SP3 in which the first type subpixels SP1 and the second to third type subpixels SP2 and SP3 are alternately disposed in the first direction X.

Referring to FIGS. 8 to 11, each pixel PX may include a first type subpixel SP1 emitting first color light, a second type subpixel SP2 emitting second color light, and a third type subpixel SP3 emitting third color light. The first type subpixel SP1 may be disposed adjacent to the second and third type subpixels SP2 and SP3 in the first direction X. The second and third type subpixels SP2 and SP3 may be disposed adjacent and parallel to each other in the second direction Y.

The first type subpixel SP1 may include a first light emitting element EL11, a first light control element L11 overlapping on the first light emitting element EL11, at least one second light emitting element EL12, and at least one second light control element L12 overlapping on the at least one second light emitting element EL12. In an embodiment, in the first type subpixel SP1, two second light emitting elements EL12 may be disposed to be separated from each other with the first light emitting element EL11 interposed therebetween in the second direction Y. The two second light emitting elements EL12 may have a parallel connection structure in which the first electrodes are connected to each other. A plurality of the second light emitting element EL12 may emit light at a same time, and the first light emitting element EL11 may not emit light when the plurality of the second light emitting element EL12 emit the light at the same time.

In the first type subpixel SP1, two second light control elements L12 may be disposed to be separated from each other with the first light control element L11 interposed therebetween in the second direction Y. The second light emitting element EL12 and the second light control element L12 of the first type subpixel SP1 may be disposed adjacent to the second light emitting element EL12 and the second light control element L12 of another first type subpixel SP1 adjacent to each other in the second direction Y.

The first type subpixel SP1 may be a red subpixel having first and second light emitting elements EL11 and EL12 that emit red light.

The second type subpixel SP2 may include a first light emitting element EL21, a first light control element L21 overlapped on the first light emitting element EL21, at least one second light emitting element EL22, and at least one second light control element L22 overlapped on the at least one second light emitting element EL22.

In the second type subpixel SP2, two second light emitting elements EL22 may be disposed in parallel in the first direction X, and the first light emitting element EL21 and the two second light emitting elements EL22 may be separated from each other in the second direction Y. The two second light emitting elements EL22 may have a parallel connection structure in which the first electrodes are connected to each other.

In the second type subpixel SP2, two second light control elements L22 may be disposed in parallel in the first direction X, and the first light control element L21 and the two second light control elements L22 may be disposed separately in the second direction Y.

The second type subpixel SP2 may be a green subpixel having first and second light emitting elements EL21 and EL22 that emit green light.

In the third type subpixel SP3, two second light emitting elements EL32 may be disposed in parallel in the first direction X, and the first light emitting element EL31 and the two second light emitting elements EL32 may be separated from each other in the second direction Y. The two second light emitting elements EL32 may have a parallel connection structure in which the first electrodes are connected to each other.

In the third type subpixel SP3, two second light control elements L32 may be disposed in parallel in the first direction X, and the first light control element L31 and the two second light control elements L32 may be disposed separately in the second direction Y.

The second light emitting element EL22 and the second light control element L22 of the second type subpixel SP2 may be disposed adjacent to the second light emitting element EL32 and the second light control element L32 of the third type subpixel SP3 of the same pixel PX adjacent to each other in the second direction Y. The first light emitting element EL31 and the first light control element L31 of the third type subpixel SP3 may be disposed adjacent to the first light emitting element EL21 and the first light control element L21 of the second type subpixel SP2 of another pixel PX adjacent to each other in the second direction Y.

The third type subpixel SP3 may be a blue subpixel having first and second light emitting elements EL31 and EL32 that emit blue light.

The size of the first light emitting elements EL1: EL11, EL21, and EL31 may be larger than the size of the second light emitting elements EL2: EL12, EL22, and EL32. The size of the lower surfaces of the first light control elements L1: L11, L21, and L31 may be set larger than the size (the size of the light emitting area) of the first light emitting elements EL1: EL11, EL21, and EL31, so that the light emitting efficiency may be improved. The size of the lower surfaces of the second light control elements L2: L12, L22, and L32 may be set larger than the size (the size of the light emitting area) of the second light emitting elements EL2: EL12, EL22, and EL32, so that the light emitting efficiency may be improved.

In an embodiment, the sizes of the first light emitting elements EL11, EL21, and EL31 may be different for each color to compensate for a deviation in light emission efficiency for each color of the first light emitting elements EL11, EL21, and EL31. In an embodiment, the sizes of the first light emitting element EL11 and the first light control element L11 of the first type subpixel SP1 may be the smallest, and the sizes of the first light emitting element EL21 and the first light control element L21 of the second type subpixel SP2 may be equal to or smaller than the sizes of the first light emitting element EL31 and the first light control element L31 of the third type subpixel SP3.

In an embodiment, the sizes of the second light emitting elements EL12, EL22, and EL32 may be different for each color, or the number of light emitting regions having the same size may be different for each color to compensate for a variation in light emission efficiency for each color of the second light emitting elements EL12, EL22, and EL32. In an embodiment, the sizes (number) of the second light emitting element EL12 and the second light control element L12 of the first type subpixel SP1 may be the smallest, and the sizes (number) of the second light emitting element EL22 and the second light control element L22 of the second type subpixel SP2 may be equal to or smaller than the sizes (number) of the second light emitting element EL32 and the second light control element L32 of the third type subpixel SP3.

The touch sensor array may include a plurality of sensor electrodes SE, a plurality of dummy electrodes DSE, and a plurality of bridge electrodes BE disposed to overlap the non-light emitting area of the pixel array. The plurality of sensor electrodes SE and the plurality of dummy electrodes DSE may be disposed on the same layer to be separated from each other. The bridge electrode BE may be disposed on a different layer to overlap the sensor electrode SE and the dummy electrode DSE, and may electrically connect the plurality of sensor electrodes SE through the contact part CNT.

In an embodiment, a plurality of sensor electrodes SE may be disposed in a non-light emitting area of the first type subpixel SP1 along the 2m−1 column line C2m−1. A plurality of sensor electrodes SE may be separated in the second direction Y with the first light emitting element EL11 of the first type subpixel SP1 interposed therebetween.

Each of the plurality of sensor electrodes SE may include a first sensor electrode portion SE1 disposed in the non-light emitting area around the second light emitting element EL12 of the first type subpixel SP1 and a second sensor electrode portion SE2 disposed in the non-light emitting area around the second light emitting element EL22 of another second type subpixel SP2 adjacent to each other in the second direction Y. Each of the plurality of sensor electrodes SE may further include a third sensor electrode portion SE3 connecting the first sensor electrode portion SE1 to the second sensor electrode portion SE2 in the second direction Y.

In each of the first sensor electrode portion SE1 and the second sensor electrode portion SE2, a first portion surrounding the second light emitting element EL12 may have a relatively large area, a second portion overlapping the contact part CNT may have a smaller area than the first portion, and the third sensor electrode portion SE3 may have the smallest area.

The first sensor electrode portion SE1 and the second sensor electrode portion SE2 may be connected to the third sensor electrode portion SE3, respectively, so that the first sensor electrode portion SE1, the second sensor electrode portion SE2, and the third sensor electrode portion SE3 may be integrally formed. In this case, the first sensor electrode portion SE1, the second sensor electrode portion SE2, and the third sensor electrode portion SE3 forming an integral body may be positioned in an area between the first type subpixel SP1 located on the 2nth row line R2n and the first type subpixel SP1 located on the 2n+1 row line R2n+1, for example. More specifically, the first sensor electrode portion SE1 overlaps the first type subpixel SP1 located on the 2n+1 row line R2n+1, the second sensor electrode portion SE2 overlaps the first type subpixel SP1 located on the 2n row line R2n, and the third sensor electrode portion SE3 may be integrally formed together with the first sensor electrode portion SE1 and the second sensor electrode portion SE2 by being positioned in an area between the first type subpixel SP1 located on the 2n+1 row line R2n+1 and the first type subpixel SP1 located on the 2nth row line R2n.

The first sensor electrode portion SE1 and the second sensor electrode portion SE2 may have structures symmetrical in the second direction Y with respect to the third sensor electrode portion SE3.

Each of the first sensor electrode portion SE1 and the second sensor electrode portion SE2 may be electrically connected to the bridge electrode BE through the contact part CNT adjacent to the third sensor electrode portion SE3 in the second direction Y. Two contact parts CNTs may be disposed in parallel in the second direction Y between the second light emitting elements EL12 of the first type subpixel SP1 adjacent to each other in the second direction Y, and the third sensor electrode portion SE3 may be disposed between the two contact parts CNT.

Each of the first sensor electrode portion SE1 and the second sensor electrode portion SE2 may include an opening part OH1 overlapping the light emitting area of the second light emitting element EL12 and overlapping the second light control element L12. The size of the opening part OH1 of each of the first and second sensor electrode portions SE1 and SE2 may be larger than the size of the light emitting area of the second light emitting element EL12 and smaller than the size of the lower surface of the second light control element L12. The first and second sensor electrode portions SE1 and SE2 may limit viewing angles of light emitted from the second light emitting element EL12 in the first and second directions X and Y and prevent light leakage.

The first sensor electrode portion SE1 and the second sensor electrode portion SE2 may have structures symmetrical in the second direction Y. The first sensor electrode portion SE1 and the second sensor electrode portion SE2 may be electrically connected to the bridge electrode BE through the contact part CNT.

The ends of the first sensor electrode portion SE1 and the second sensor electrode portion SE2 separated in the second direction Y with the first light emitting element EL11 of the first type sub pixel SP1 interposed therebetween overlap with a portion of the first light emitting element EL11 that is not overlapped with the first light control element L11, so that a viewing angle of light emitted from the first light emitting element EL11 in the second direction Y may be limited and light leakage may be prevented.

In an embodiment, each of a plurality of bridge electrodes BEs may pass through non-light emitting areas of the first to third type subpixels SP1, SP2, and SP3 and may be disposed along the second direction Y.

The bridge electrode BE may include first and second bridge electrode portions BE1 and BE2 extending in the second direction Y or along the 2m−1 column line C2m−1 and a third bridge electrode portion BE3 connecting the first bridge electrode portion BE1 to the second bridge electrode portions. The first and second bridge electrode portions BE1 and BE2 may overlap the first sensor electrode SE around the second light emitting element EL12 of the first type subpixel SP1, and overlap the dummy electrode DSE around the second light emitting elements EL22 and EL32 of the second and third type subpixels SP2 and SP3.

The third bridge electrode portion BE3 may be electrically connected to the first sensor electrode portion SE1 and the second sensor electrode portion SE2 through the contact part CNT. Two contact parts CNTs may be disposed in parallel in the second direction Y between the second light emitting elements EL12 of the first type subpixel SP1, which are adjacent to each other in the second direction Y

A plurality of dummy electrodes DSE may be disposed in the non-light emitting area of the 2m column line C2m. The plurality of dummy electrodes DSE may include a first dummy electrode DSE1 disposed in the non-light emitting area around the second light emitting elements EL22 and EL32 of the second and third type subpixels SP2 and SP3 adjacent to each other in the second direction Y, and a second dummy electrode DSE2 disposed in the non-light emitting area between the first light emitting elements EL21 and EL31 of the second and third type subpixels SP2 and SP3 adjacent to each other in the second direction Y. The first dummy electrode DSE1 may have an area larger than that of the second dummy electrode DSE2. The first and second dummy electrodes DSE1 and DSE2 may be floating electrodes that are not electrically connected to other electrodes. The floating first and second dummy electrodes DSE1 and DSE2 may reduce parasitic capacitance formed between the touch sensor array and the common cathode electrode of the pixel array, thereby reducing distortion of a touch driving signal and a touch sensing signal, thereby improving sensing performance.

The first dummy electrode DSE1 may include an open part OH2 overlapping the light emitting area of the second light emitting elements EL22 and EL32, and overlapping the second light control elements L22 and L32. The size of the open part OH2 of the first dummy electrode DSE1 may be larger than the size of the light emitting areas of the second light emitting elements EL22 and EL32 and smaller than the size of the lower surfaces of the second light control elements L22 and L32. The first dummy electrode DSE1 may limit viewing angles of light emitted from the second light emitting elements EL22 and EL32 in the first and second directions X and Y and prevent light leakage.

The ends of the first dummy electrode DSE1 and the second dummy electrode DSE2 in the second direction Y overlap portions of the first light control elements L21 and L31 that do not overlap the first light emitting elements EL21 and EL31, thereby limiting the viewing angle of light emitted from the first light emitting elements EL21 and EL31 in the second direction Y and preventing light leakage.

Referring to FIGS. 9 and 11, the touch sensor array may further include a black matrix BM disposed in a non-emitting area of the pixel array. The black matrix BM may be disposed between the sensor electrode SE and the bridge electrode BE and/or between the dummy electrode DSE and the bridge electrode BE.

The black matrix BM may include a first opening BH1 overlapping the first light emitting elements EL1: EL11, EL21, and EL31, and a second opening BH2 overlapping the second light emitting elements EL22, EL22, and EL32. The size of the first opening BH1 of the black matrix BM may be larger than the size of the light emitting area of the second light emitting elements EL2: EL21, EL22, and EL32, and may be larger or smaller than the size of the bottom surfaces of the second light control elements L2: L12, L22, and L32. Also, the size of the second opening BH2 of the black matrix BM may be larger than the size of the light emitting area of the first light emitting elements EL1: EL11, EL21, and EL31, and may be larger or smaller than the size of the bottom surfaces of the first light control elements L1: L11, L21, and L31. The black matrix BM may limit viewing angles in the second direction Y of light emitted from the first light emitting elements EL1: EL11, EL21, and EL31, and limit viewing angles in the first and second directions X and Y of light emitted from the second light emitting elements EL2: EL21, EL22, and EL32, as well as prevent light leakage.

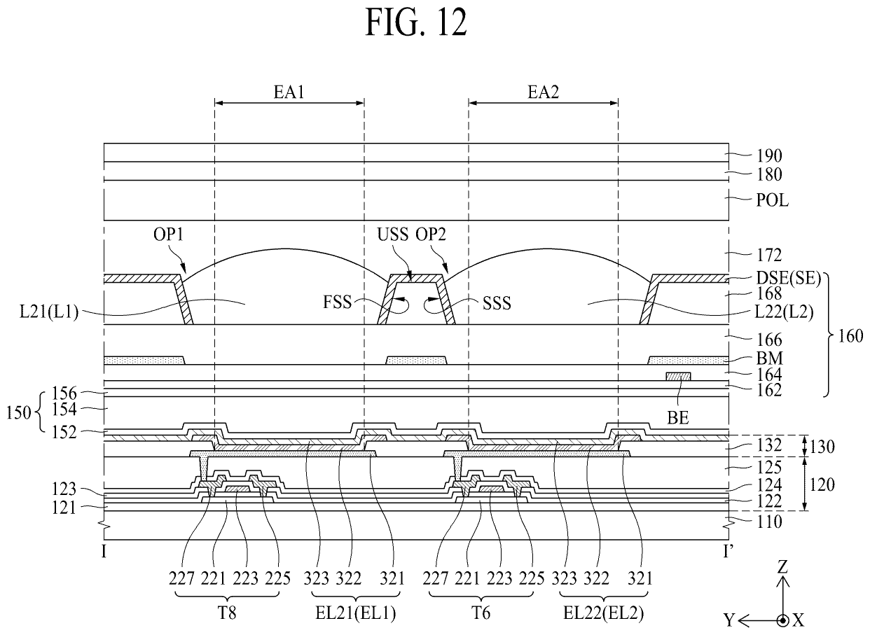

FIG. 12 is a cross-sectional view illustrating a structure of a subpixel area along a cutting line I-I′ in a pixel area illustrated in FIG. 11.

Referring to FIG. 12, the display panel 100 according to an embodiment may include a pixel array 140 including a circuit element layer 120 disposed on the substrate 110 and a light emitting element layer 130 disposed on the circuit element layer 120, an encapsulation layer 150 disposed on the pixel array 140 to seal the light emitting element layer 130, a touch sensor array 160 disposed on the encapsulation layer 150, and a light control array L1, L2, and 172 disposed on the touch sensor array 160. The display panel 100 may further include an optical film POL disposed on the light control array L1, L2, and 172, an optical transparent adhesive (OCA) 180, a cover substrate 190, and the like. In this case, the optical film POL may be, for example, a polarizing plate, but is not limited thereto.

A cross-sectional structure of the second type subpixel SP2 among the first to third type subpixels SP1, SP2, and SP3 in the display panel 100 according to an embodiment will be described as an example with reference to FIG. 12. The first to third type subpixels SP1, SP2, and SP3 may have the same cross-sectional structure.

The second type subpixel SP2 may include the switching transistors T8 and T6 of the pixel circuit 10, the first light emitting element EL21 connected to the switching transistor T8, the second light emitting element EL22 connected to the switching transistor T6, the first light control elements L1: L21 overlapping the first light emitting area EA1 on the first light emitting element EL21, and the second light control elements L2: L22 overlapping the second light emitting area EA2 on the second light emitting element EL22.

The circuit element layer 120 according to an embodiment may include a plurality of insulating layers stacked on the substrate 110. For example, a plurality of insulating layers may include a buffer layer 121, a gate insulating layer 122, an interlayer insulating layer 123, a protective layer 124, and a planarization layer 125.

The substrate 110 may include an insulating material such as glass or plastic. The plastic substrate may be formed of a flexible material. For example, the substrate 110 may include at least one organic insulating material among an acrylic resin, an epoxy resin, a siloxane resin, a polyimide resin, and a polyamide resin.

The buffer layer 121 may have a single layer or multilayer structure including an inorganic insulating material such as silicon oxide (SiOx), silicon nitride (SiNx), aluminum oxide (Al₂O₃). The buffer layer 121 may prevent an impurity such as hydrogen from being introduced into the semiconductor layer 221 through the substrate 110.

A plurality of transistors including switching transistors T8 and T6 may be disposed on the buffer layer 121.

In an embodiment, the buffer layer 121 may include a multi-buffer layer and an active buffer layer. In this case, a multi-buffer layer may be disposed on the substrate 110 and an active buffer layer may be disposed on the multi-buffer layer. A light blocking layer may be disposed between the multi-buffer layer and the active buffer layer.

Each of the switching transistors T8 and T6 includes a semiconductor layer 221, a gate electrode 223, a source electrode 225 and a drain electrode 227 disposed on the buffer layer 121. The gate insulating layer 122 is disposed between the semiconductor layer 221 and the gate electrode 223. The interlayer insulating layer 123 is disposed between the gate electrode 223 and the source and drain electrodes 225 and 227. The source electrode 225 and the drain electrode 227 of each of the switching transistors T8 and T6 may be connected to the source region and the drain region of the semiconductor layer 221, respectively, through contact holes penetrating the interlayer insulating layer 123 and the gate insulating layer 122.

The semiconductor layer 221 may include polycrystalline silicon, or may include an oxide semiconductor material. The semiconductor layer 221 may include low-temperature polysilicon (LTPS). The semiconductor layer 221 may include at least one oxide semiconductor material among an IZO (InZnO)-based, an IGO (InGaO)-based, an ITO (InSnO)-based, an IGZO (InGaZnO)-based, an IGZTO (InGaZnSnO)-based, a GZTO (GaZnSnO)-based, a GZO (GaZnO)-based, and an ITZO (InSnZnO)-based. A light shielding layer (not shown) may be further disposed under the semiconductor layer 221.

The gate insulating layer 122 may include an inorganic insulating material such as silicon oxide (SiOx) and silicon nitride (SiNx). The gate insulating layer 122 may include a material having a high dielectric constant. For example, the gate insulating layer 122 may include a High-K material such as hafnium oxide (HfO). The gate insulating layer 122 may have a multilayer structure.

The gate electrode 223 and the gate line may be disposed on the gate insulating layer 122.

The interlayer insulating layer 123 may include an inorganic insulating material such as silicon oxide (SiOx) and silicon nitride (SiNx). The interlayer insulating layer 123 may have a multilayer structure.

A source electrode 225 and a drain electrode 227, a data line, and a power line may be disposed on the interlayer insulating layer 123.

The protection layer 124 and the planarization layer 125 may be stacked on the switching transistors T8 and T6. The protection layer 124 may include an inorganic insulating material such as silicon oxide (SiOx) and silicon nitride (SiNx). The planarization layer 125 may include an organic insulating material different from that of the protection layer 124 and may provide a flat surface. The planarization layer 125 may have a double layer structure.

A light emitting element layer 130 including light emitting elements EL1: EL21 and EL2: EL22 may be disposed on the planarization layer 125.

Each of the first and second light emitting elements EL21 and EL22 may include a first electrode 321 disposed on the planarization layer 125, a light emitting layer 322 disposed on the first electrode 321, and a second electrode 323 disposed on the light emitting layer 322. In this case, the first electrode 321 may function as an anode electrode, and the second electrode 323 may function as a cathode electrode, for example.

The first electrode 321 of the first light emitting element EL21 may be connected to any one of the source electrode 225 and the drain electrode 227 of the switching transistor T8 through a contact hole penetrating the planarization layer 125 and the protective layer 124. The first electrode 321 of the second light emitting element EL22 may be connected to any one of the source electrode 225 and the drain electrode 227 of the switching transistor T6 through a contact hole penetrating the planarization layer 125 and the protective layer 124.

The first electrode 321 may include a conductive material having a high reflectivity. The first electrode 321 may include a metal such as aluminum (Al), silver (Ag), titanium (Ti), and a silver-palladium-copper (APC) alloy. The first electrode 321 may further include a transparent conductive material such as an indium tin oxide (ITO) or an indium zinc oxide (IZO). In an embodiment, the first electrode 321 may have a multilayer structure (Ti/Al/Ti) of titanium (Ti) and aluminum (Al), a multilayer structure (ITO/AI/ITO) of ITO and aluminum (Al), or a multilayer structure (ITO/APC/ITO) of ITO and APC.

The light emitting layer 322 may include an emission material layer (EML) including a light emitting material. The light emitting material may include an organic material, an inorganic material, or a hybrid material. The light emitting layer 322 may have a multilayer structure. In an embodiment, the light emitting layer 322 may further include at least one of a hole injection layer (HIL), a hole transport layer (HTL), an electron transport layer (ETL), and an electron injection layer (EIL).

The cathode electrode 323 may be a common electrode and may include a conductive material that transmits light. The cathode electrode 323 may include a transparent conductive material such as ITO or IZO. The cathode electrode 323 may include aluminum (Al), magnesium (Mg), silver (Ag), or an alloy thereof and may have a thin thickness capable of transmitting light. Light generated by the light emitting layer 322 may be emitted through the cathode electrode 323.

The bank insulating layer 132 may be positioned on the first electrode 321 of the first and second light emitting elements EL21 and EL22. The first electrodes 321 of the first and second light emitting elements EL21 and EL22 are spaced apart from each other, and the bank insulating layer 132 may be positioned between the first electrodes 321 of the first and second light emitting elements EL21 and EL22. The bank insulating layer 132 may cover the edge of the first electrode 321. The bank insulating layer 132 may include an organic insulating material. The bank insulating layer 132 may include an organic material different from that of the planarization layer 125, and may have a single layer or a double layer structure.

The bank insulating layer 132 may include a plurality of open parts through which the first electrodes 321 of the first and second light emitting elements EL21 and EL22 are exposed to define a plurality of light emitting areas EA1 and EA2. For example, the bank insulating layer 132 may define a first light emitting area EA1 including an opening through which the first electrode 321 of the first light emitting element EL21 is exposed, and may define a second light emitting area EA2 including an opening through which the first electrode 321 of the second light emitting element EL22 is exposed. The light emitting layer 322 and the cathode electrode 323 of the first and second light emitting elements EL21 and EL22 may be stacked on the first electrode 321 exposed by the open part of the bank insulating layer 132.

The encapsulation layer 150 may be positioned on the light emitting element layer 130 including the first and second light emitting elements EL21 and EL22. The encapsulation layer 150 may prevent damage to the light emitting elements EL21 and EL22 due to external moisture and impact. The encapsulation layer 150 may have a multilayer structure. In an embodiment, the encapsulation layer 150 may include a first encapsulation layer 152, a second encapsulation layer 154, and a third encapsulation layer 156 that are sequentially stacked, but is not limited thereto. The first encapsulation layer 152, the second encapsulation layer 154, and the third encapsulation layer 156 may include an insulating material. The second encapsulation layer 154 may include a material different from that of the first encapsulation layer 152 and the third encapsulation layer 156. For example, the first encapsulation layer 152 and the third encapsulation layer 156 are inorganic encapsulation layers including an inorganic insulating material, and the second encapsulation layer 154 may include an organic encapsulation layer including an organic insulating material. Accordingly, the light emitting elements EL21 and EL22 of the display apparatus may be more effectively prevented from being damaged by external moisture and impact.

The touch sensor array 160 includes a first touch insulating layer 162 disposed on the encapsulation layer 150, a bridge electrode BE disposed on the first touch insulating layer 162, a second touch insulating layer 164 covering the bridge electrode BE, a black matrix BM disposed on the second touch insulating layer 164, a third touch insulating layer 166 covering the black matrix BM, a fourth touch insulating layer 168 disposed on the third touch insulating layer 166, and the sensor electrode SE and the dummy sensor electrode DSE disposed on the fourth touch insulating layer 168. The bridge electrode BE, the black matrix BM, the sensor electrode SE and the dummy sensor electrode DSE may be disposed in a non-light emitting area overlapping the bank insulating layer 132. The bridge electrode BE may be connected to the sensor electrode (see SE in FIG. 10) and the contact part (see CNT in FIG. 10) to electrically connect the sensor electrode SE to the other sensor electrode SE. For example, the bridge electrode BE may electrically connect the first sensor electrode (see SE1 in FIG. 10) and the second sensor electrode (see SE2 in FIG. 10).

The black matrix BM is disposed on the bridge electrode BE and may overlap the entire bridge electrode BE. Since the bridge electrodes BE are completely covered by the black matrix BM, the problem of external light being reflected by the bridge electrodes BE can be prevented and the visibility of the display panel (see 100 in FIG. 1) can be improved.

The third touch insulating layer 166 may cover the black matrix BM and may be formed on the entire surface of the substrate 110. However, it is not limited thereto.

A fourth touch insulating layer 168 may be disposed on the third touch insulating layer 166. A plurality of openings OP1 and OP2 may be formed in the fourth touch insulating layer 164. Specifically, the first opening OP1 is formed in a portion overlapping the first light emitting area EA1, and the second opening OP2 is formed in the portion overlapping the second light emitting area EA2. As the first opening OP1 and the second opening OP2 are formed, a portion of the upper surface of the third touch insulating layer 166 may be exposed. In this case, the portion of the third touch insulating layer 166 exposed by the first opening OP1 and the second opening OP2 will overlap the first light emitting element EL21 and the second light emitting element EL22, respectively.

The fourth touch insulating layer 168, for example, the fourth touch insulating layer 168 disposed between the first light control element L21 and the second light control element L22 may include a first side surface FSS in contact with the first opening OP1 and facing the first light control element L21, a second side surface SSS in contact with the second opening OP2 and facing the second light control element L22, and an upper surface USS (or top surface USS) continuously connected between the first side surface FSS and the second side surface SSS.

A sensor electrode SE and/or a dummy sensor electrode DSE may be disposed on the fourth touch insulating layer 168. The dummy sensor electrode DSE may cover the top surface USS and side surfaces FSS, SSS of the fourth touch insulating layer 168. For example, the dummy sensor electrode DSE may cover the first side surface FSS, the second side surface SSS and the upper surface USS of the fourth touch insulating layer 168 disposed between the first light control element L21 and the second light control element L22. The sensor electrode SE may correspond to an area disposed between the first emitting area EA1 and the second emitting area EA2. The sensor electrode SE may be disposed on the first side surface FSS and the upper surface USS of the fourth touch insulating layer 168. The sensor electrode SE may be continuously and contiguously disposed on the first side surface FSS of the fourth touch insulating layer 168 and the upper surface of the fourth touch insulating layer 168. The sensor electrode SE may be in contact with an upper surface of the third touch insulating layer 166 in the first opening OA1. The sensor electrode SE disposed on the first side surface FSS of the fourth touch insulating layer 168 may face the first light control element L21. The sensor electrode SE may include a first portion facing the first light control element L21 and a second portion facing the second light control element L22.

According to an embodiment, since the dummy sensor electrode DSE covers the side surface of the fourth touch insulating layer 168, even if the light emitted from the first light emitting area EA1 or the second light emitting area EA2 travels at a predetermined angle or more, it is reflected by the sensor electrode SE or the dummy sensor electrode DSE disposed on the side surface of the fourth touch insulating layer 168 to face the front. Accordingly, luminance at the front of the display panel (refer to 100 in FIG. 1) according to one embodiment may be improved.

The dummy sensor electrode DSE may not be disposed in the first light emitting area EA1 and the second light emitting area EA2, but may be disposed to correspond to an area located between the first light emitting area EA1 and the second light emitting area EA2. As a result, the dummy sensor electrode DSE continuously and contiguously covers the side surfaces FSS, SSS and the upper surface USS of the fourth touch insulating layer 168 and does not overlap the first and second light emitting areas EA1 and EA2 from a plan view.

A portion of the dummy sensor electrode DSE, for example, the dummy sensor electrode DSE covering the side surface of the fourth touch insulating layer 168, is partially disposed in the first opening OP1 and the second opening OP2, and the portion of the dummy sensor electrode DSE may contact a portion of the upper surface of the third touch insulating layer 166 exposed by the first opening OP1 and the second opening OP2. Furthermore, the dummy sensor electrode DSE may extend to the upper surface of the third touch insulating layer 166, so that the lower end of the dummy sensor electrode DSE is connected to the first light control element L21 and the second light control element L22.

The dummy sensor electrode DSE, for example, the dummy sensor electrode DSE disposed between the first light control element L21 and the second light control element L22, may include a first portion disposed on one side, for example, the left side of the fourth touch insulating layer 168, and facing the first light control element L21, and a second portion disposed another side, for example, the right side of the fourth touch insulating layer 168, and facing the second light control element L22, and a third portion continuously connected between the first portion and the second portion. As the first portion to the third portion of the dummy sensor electrode DSE is connected continuously, the fourth touch insulating layer 168 disposed between the first light control element L21 and the second light control element L22 may be covered by the dummy sensor electrode DSE.

The light control array L1, L2, and 172 including a first light control element L21 and a second light control element L22 may be disposed on the touch sensor array 160. Specifically, the first light control element L21 and the second light control element L22 may be formed, for example, after the touch sensor array 160 is formed.

The first light control element L21 and the second light control element L22 may be disposed in the plurality of openings OP1 and OP2 on the same layer as the fourth touch insulating layer 168. Specifically, the first light control element L21 is disposed in the first opening OP1 so that the first light control element L21 overlaps the first opening OP1, and the second light control element L22 is disposed in the second opening OP2 so that the second light control element L22 overlaps the second opening OP2. In this case, the first light control element L21 within the first opening OP1 may be disposed at the same height as the bottom of the dummy sensor electrode DSE, and the second light control element L22 within the second opening OP2 may be disposed at the same height as the bottom of the dummy sensor electrode DSE.

As the first light control element L21 is disposed in the first opening OP1, the first light control element L21 is surrounded by the fourth touch insulating layer 168 and the dummy sensor electrode DSE, and as the light control element L22 is disposed in the second opening OP2, the second light control element L22 may be surrounded by the fourth touch insulating layer 168 and the dummy sensor electrode DSE.

By forming in this way, even if the light emitted from the first light emitting area EA1 is refracted while passing through the first light control element L21, the light refracted more than necessary may be reflected by the dummy sensor electrode DSE disposed around the first light control element L21 to emit light to the front of the display panel (see 100 of FIG. 1), and even if the light emitted from the second light emitting area EA2 is refracted while passing through the second light control element L22, the light refracted more than necessary may be reflected by the dummy sensor electrode DSE disposed around the second light control element L22 to emit light to the front of the display panel (see 100 of FIG. 1). Furthermore, the light extraction efficiency of the display apparatus may be improved by the dummy sensor electrode DSE surrounding the first light control element L21 and the second light control element L22. And, by improving the lifespan of the display apparatus according to an embodiment, low power driving is possible in terms of production energy reduction.

The first light control element L21 overlaps the light emitting area EA1 of the first light emitting element EL21, and the second light control element L22 overlaps the light emitting area EA2 of the second light emitting element EL22. The first light control element L21 and the second light control element L22 may be disposed in the light emitting area EA1 of the first light emitting element EL21 and the light emitting area EA2 of the second light emitting element EL22 to control a path of light generated in the light emitting areas EA1 and EA2, respectively.

The first light control element L21 may control the traveling path of light generated in the light emitting area EA1 of the first light emitting element EL21 to be a wide viewing angle in the first direction X and to be a narrow viewing angle in the second direction Y, and may control the traveling path of light generated in the light emitting area EA2 of the second light emitting element EL22 to be a narrow viewing angle in the first and second directions X and Y.

The protective layer 172 may be positioned on the first light control element L21 and the second light control element L22. The protective layer 172 may include an organic insulating material. The refractive index of the protective layer 172 may be less than the refractive index of the first light control element L21 and the refractive index of the second light control element L22. Thus, the light passing through the first light control element L21 and the second light control element L22 may not be reflected toward the substrate 110 due to the difference in refractive index from the protective layer 172.

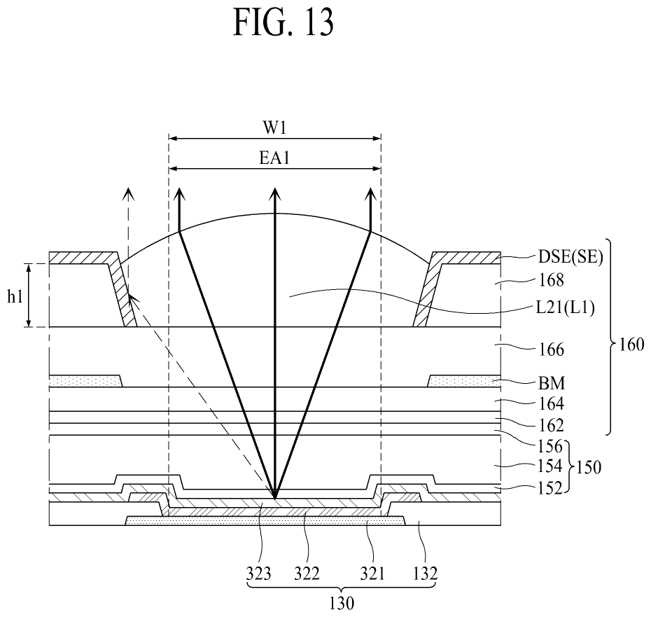

FIG. 13 is a cross-sectional view schematically showing the pixel area shown in FIG. 12. In this case, FIG. 13 schematically shows the first light emitting area according to the embodiment of FIG. 12. Meanwhile, in FIG. 13, the same reference numerals are given to components overlapping with those of FIG. 12, and repeated descriptions will be omitted.

Referring to FIG. 13, light emitted from the first light emitting area EA1 (portion indicated by a solid line) passes through the encapsulation layer 150, the touch sensor array 160, and the first light control element L21. In this case, even if the light emitted from the first light emitting area EA1 is emitted at a certain angle, the light that was directed to the side is directed to the front by the first light control element L21. By forming in this way, the viewing angle in the first light emitting area EA1 can be controlled and the light emitting efficiency from the front can be improved. Meanwhile, according to one embodiment, the fourth touch insulating layer 168 may have a first height h1, and the first light emitting area EA1 may have a first size W1.

Light (a portion indicated by a dotted line) emitted from the first light emitting area EA1 is reflected by the dummy sensor electrode DSE (or the sensor electrode SE) disposed around the first light control element L21 and faces the front direction of the display panel (see 100 in FIG. 1). By forming in this way, light emission efficiency at the front surface may be improved.

Meanwhile, in FIG. 13, light emitted from the first light emitting area EA1 of the first light emitting element EL21 is reflected by the dummy sensor electrode DSE (or sensor electrode SE), but the present disclosure is not limited thereto, and may be equally applied to all of the plurality of light emitting elements EL11, EL12, EL22, EL31, and EL32.

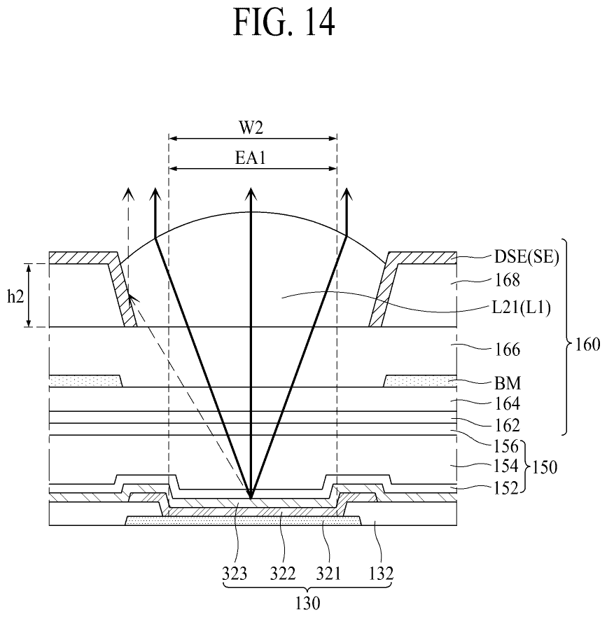

FIG. 14 is a cross-sectional view schematically illustrating a pixel area illustrated in FIG. 12. In this case, FIG. 14 schematically illustrates a first light emitting area according to another embodiment of FIG. 12. Meanwhile, in FIG. 14, the same reference numerals are assigned to configurations overlapping with those of FIG. 12, and repeated descriptions thereof will be omitted.

Referring to FIG. 14, when the light (a portion indicated by a solid line) emitted from the first light emitting area EA1 passes through the encapsulation layer 150, the touch sensor array 160, and the first light control element L21, even if the light emitted from the first light emitting area EA1 is emitted at a certain angle, the light directed sideways by the first light control element L21 faces the front. By forming in this way, it is possible to control the viewing angle in the first light emitting area EA1 and improve light emission efficiency in the front. Meanwhile, according to another embodiment, the fourth touch insulating layer 168 may have a second height h2, unlike FIG. 13, and the first light emitting area EA1 may have a second size W2, unlike FIG. 13. In this case, the second height h2 may be relatively smaller than the first height h1, and the second size W2 may be relatively smaller than the first size W1.

Referring to FIG. 14, when the size of the first light emitting area EA1 is designed to be smaller than the embodiment of FIG. 13, the height of the fourth touch insulating layer 168 may be adjusted to the second height h2 so that the light emitted from the first light emitting area EA1 is reflected through the dummy sensor electrode DSE. As a result, referring to FIGS. 13 and 14, it is possible to improve light emission efficiency from the front by adjusting the height of the fourth touch insulating layer 168 according to the size of the light emitting area to be designed. Therefore, when the size of the first light emitting area EA1 to be designed is relatively large, for example, in the case of the first size W1, the height of the fourth touch insulating layer 168 is relatively large, for example, by setting it as the first height h1, and the light emitted from the first light emitting area EA1 is reflected by the dummy sensor electrode DSE to face the front, and when the size of the first light emitting area EA1 to be designed is relatively small, for example, in the case of the second size W2, the height of the fourth touch insulating layer 168 may be relatively small, for example, by setting it as the second height h2, and the light emitted from the first light emitting area EA1 may be reflected by the dummy sensor electrode DSE to face the front.

Accordingly, the present disclosure may have the following advantages.

According to an embodiment of the present disclosure, sensor electrodes and/or dummy sensor electrodes are disposed to cover the upper surface and side surface of the touch insulating layers having a plurality of openings, and light control elements are disposed thereon, so that light emitted from the light emitting area is reflected by the sensor electrodes and/or dummy sensor electrodes to face the front, thereby increasing light emission efficiency in front of the display panel.

According to an embodiment of present disclosure, by appropriately adjusting the height of the touch insulating layer with the plurality of openings in accordance with the size of the light emitting element to be designed, it is possible to easily implement a display panel that satisfies the required light emitting efficiency condition.

According to an embodiment of the present disclosure, light extraction efficiency of a display apparatus may be improved. Accordingly, the embodiment improves the lifetime of the display apparatus, thereby enabling low power driving in terms of reducing production energy.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate including a first emitting area and a second emitting area;
a first insulating layer disposed on the substrate, the first insulating layer including a first opening corresponding to the first light emitting area and a second opening corresponding to the second light emitting area; and
a sensor electrode disposed on the first insulating layer, the sensor electrode corresponding to an area disposed between the first emitting area and the second emitting area,
wherein the first insulating layer includes a first side surface in contact with the first opening and an upper surface connected to the first side surface, and
wherein the sensor electrode is disposed on the first side surface and the upper surface of the first insulating layer.

2. The display apparatus according to claim 1,
wherein the sensor electrode is continuously and contiguously disposed on the first side surface of the first insulating layer and the upper surface of the first insulating layer.

3. The display apparatus according to claim 1, further comprising:
a second insulating layer disposed under the first insulating layer and exposed through the first opening,
wherein the sensor electrode is in contact with an upper surface of the second insulating layer in the first opening.

4. The display apparatus according to claim 1, further comprising:
a bridge electrode connected to the sensor electrode through a contact part.

5. The display apparatus according to claim 4, further comprising:
a black matrix overlapping the sensor electrode,
wherein the black matrix is disposed between the sensor electrode and the bridge electrode.

6. The display apparatus according to claim 5,
wherein the black matrix overlaps all of the bridge electrodes.

7. The display apparatus according to claim 1, further comprising:
a first light control element overlapping the first opening; and
a second light control element overlapping the second opening.

8. The display apparatus according to claim 7,
wherein the first light control element is disposed on a same layer as the first insulating layer.

9. The display apparatus according to claim 7,
wherein the sensor electrode disposed on the first side surface of the first insulating layer faces the first light control element.

10. The display apparatus according to claim 7, further comprising:
a second insulating layer disposed under the first insulating layer and exposed through the first opening,
wherein the first light control element is in contact with an upper surface of the second insulating layer in the first opening.

11. The display apparatus according to claim 7,
wherein a size of the first light control element is larger than a size of the first light emitting area.

12. The display apparatus according to claim 7, further comprising a dummy sensor electrode disposed on the first insulating layer,
wherein the dummy sensor electrode covers the first side surface, the second side surface and the upper surface of the first insulating layer disposed between the first light control element and the second light control element.

13. The display apparatus according to claim 12,
wherein the dummy sensor electrode is a floating electrode that is not electrically connected to other electrodes, and
wherein the sensor electrode and the dummy sensor electrode are disposed on a same layer to be separated from each other.

14. The display apparatus according to claim 12, wherein the dummy sensor electrode disposed between the first light control element and the second light control element includes:
a first portion disposed on one side of the first insulating layer and facing the first light control element;
a second portion disposed another side of the first insulating layer and facing the second light control element; and
a third portion continuously connected between the first portion and the second portion.

15. The display apparatus according to claim 7,
wherein the first light control element within the first opening is disposed at a same height as a bottom of the dummy sensor electrode, and the second light control element within the second opening is disposed at a same height as a bottom of the dummy sensor electrode.

16. A display apparatus, comprising:
a plurality of light emitting elements including a first light emitting element and a second light emitting element;
a first light control element disposed in the first light emitting element;
a second light control element disposed in the second light emitting element; and
a sensor electrode disposed between the first light emitting element and the second light emitting element,
wherein the sensor electrode is disposed between the first light control element and the second light control element, and the sensor electrode includes a first portion facing the first light control element and a second portion facing the second light control element.

17. The display apparatus according to claim 16,
wherein the first light emitting element and the second light emitting element emit light of a same color, and
wherein the second light emitting element faces the first light emitting element, and the second light emitting element includes a plurality of second light emitting elements.

18. The display apparatus according to claim 17,
wherein the plurality of the second light emitting element emit light at a same time, and the first light emitting element does not emit light when the plurality of the second light emitting element emit the light at the same time.

19. The display apparatus according to claim 16,
wherein a size of the first light emitting element is larger than a size of the second light emitting element.

20. The display apparatus according to claim 16,
wherein the first light control element has a semi-cylindrical shape, and the first light emitting element is driven in a wide viewing angle mode, and
wherein the second light control element has a hemispherical shape and the second light emitting element is driven in a narrow viewing angle mode.

21. The display apparatus according to claim 16, further comprising:
a bridge electrode connected to the sensor electrode through a contact part; and
a black matrix disposed between the sensor electrode and the bridge electrode.

22. The display apparatus according to claim 21,
wherein the black matrix includes a first opening overlapping the first light emitting element and a second opening overlapping the second light emitting element, and
wherein a size of the first opening of the black matrix is greater than a size of a light emitting area of the second light emitting element, and a size of the second opening of the black matrix is greater than a size of a light emitting area of the first light emitting element.

23. The display apparatus according to claim 16, further comprising a first insulating layer including a first opening corresponding to a first light emitting area of the first light emitting element and a second opening corresponding to a second light emitting area of the second light emitting element.

24. The display apparatus according to claim 23, wherein the first insulating layer disposed between the first light control element and the second light control element include:
a first side surface in contact with the first opening and facing the first light control element;
a second side surface in contact with the second opening and facing the second light control element; and
an upper surface continuously connected between the first side surface and the second side surface.

25. The display apparatus according to claim 24, further comprising a dummy sensor electrode disposed on the first insulating layer,
wherein the dummy sensor electrode covers the first side surface, the second side surface and the upper surface of the first insulating layer disposed between the first light control element and the second light control element.
